(19) United States
(12) Patent Application Publication
(10) Pub. No.: US 2006/0102931 A1
(43) Pub. Date: May 18, 2006

(54) Field effect transistor having a carrier exclusion layer

(76) Inventors: Thomas Edward Kopley, La Honda, CA (US); Mark Robert Hueschen, Palo Alto, CA (US); Nicolas J. Moll, Woodside, CA (US)

Correspondence Address: AGILENT TECHNOLOGIES, INC.;INTELLECTUAL PROPERTY ADMINISTRATION, LEGAL DEPT., P.O. BOX 7599, M/S DL429, LOVELAND, CO, 80537-0599, US

(21) Appl. No.: 10/991,014

(22) Filed: Nov. 17, 2004

(51) Int. Cl. H01L 31/072; H01L 21/3205

(52) U.S. Cl. 257/192; 438/285; 438/590; 257/194

(57) ABSTRACT

A field-effect transistor comprises a substrate, a channel layer over the substrate, a gate insulator, a gate separated from the channel layer by the gate insulator, and a carrier exclusion layer between the channel layer and the gate insulator, wherein the conduction band energy of the carrier exclusion layer is larger than the conduction band energy of the channel layer.

### BACKGROUND OF THE INVENTION

Field effect transistors have been developed using many different processing technologies. One of the more prevalent types of transistors is referred to as a metal semiconductor field effect transistor (MESFET). A MESFET uses a metal-semiconductor contact at the gate terminal of the device. The metal-semiconductor gate forms a Schottky barrier. A MESFET device based on the gallium arsenide (GaAs) semiconductor material system can be used in a variety of applications. In a MESFET, the gate metal resides directly on the channel material. The electrical isolation between the gate and the channel material results from the Schottky barrier therebetween. A disadvantage of a GaAs MESFET is that a large forward-bias gate current limits the voltage range that may be applied to the gate.

A metal insulator field effect transistor (MISFET) includes an insulating layer located between the gate metal and the channel material. A MISFET operates at a lower gate current than a MESFET, and allows a larger voltage range to be applied to the gate. Many different materials have been implemented as the insulator of a MISFET. Unfortunately, locating an insulating layer between the gate metal and the channel material results in the formation of an insulator-channel interface which may have a high density of electron traps near the insulator-channel interface. When the insulator is an oxide this interface is also referred to as the “oxide-semiconductor” interface. These traps are also referred to as “interface traps.” Interface trap densities of 10¹³-10¹⁴ traps/centimeter-squared (cm)²/electron volt (eV) at the insulator-channel interface are common and limit the flow of electrons in the channel and cause difficulty when attempting to turn the transistor on and off. When implemented using the GaAs material system, the interface traps located at the insulator-channel interface negate the superior electron transport capability of the GaAs material system channel by forming scattering centers at the insulator-channel interface, thus reducing the electron mobility in the channel. Another result of the interface traps located at the insulator-channel interface is that the interface traps shield the charge in the channel from the gate voltage. This reduces low-frequency transconductance and reduces the performance of the transistor. The interface traps may also produce large offsets and instabilities in the transistor threshold voltage. The transistor threshold voltage, Vt, is dependent on the amount of charge in the gate oxide and at the oxide-semiconductor interface. Interface traps at the oxide-semiconductor interface charge and discharge as the gate voltage is varied. Thus, it is possible for Vt to vary when sweeping the gate voltage, Vg, of the device. This is referred to as an “instability” in the threshold voltage, Vt, since for practical device operation, the threshold voltage, Vt, should not vary. As the interface trap density becomes large, it is possible to have the threshold voltage, Vt, at a positive Vg sweep different from the threshold voltage, Vt, at negative Vg sweep, which shows up as hysteresis in the drain current as the gate voltage, Vg, is swept. For traps with fixed charge, there may not be hysteresis, but the charged interface traps may cause fixed offsets in the threshold voltage, Vt, that are non-negligible.

Large bandgap semiconductors have also been used in an attempt to minimize gate current in a MISFET. For example, aluminum gallium arsenide (AlGaAs), which grows epitaxially on GaAs, has been used as an insulator. Aluminum gallium arsenide, when used as an insulator, reduces interface trap density at the AlGaAs insulator-GaAs channel interface. Unfortunately, aluminum gallium arsenide provides a relatively low barrier to gate current.

Another attempt at reducing interface trap density at the insulator-channel interface uses oxide material deposited using atomic layer deposition (ALD). For example, aluminum oxide (Al₂O₃) deposited using ALD as an insulator in a metal oxide semiconductor field effect transistor (MOSFET) provides acceptable insulation, lower interface trap density (approximately 5×10¹¹-10¹² traps/cm²/eV) than other insulator materials, and a reasonably good barrier to gate current. Unfortunately, aluminum oxide still can result in a higher than desirable interface trap density at the insulator (oxide)-channel interface.

Therefore, it is desirable to improve the performance of a transistor having an insulator-channel interface.

### SUMMARY OF THE INVENTION

The invention provides a field-effect transistor, comprising a substrate, a channel layer over the substrate, a gate insulator, a gate separated from the channel layer by the gate insulator, and a carrier exclusion layer formed between the channel and the gate insulator, wherein the conduction band energy of the carrier exclusion layer is larger than the conduction band energy of the channel layer.

The invention additionally provides a method of making a field-effect transistor, the method comprising providing a substrate, forming a channel layer over the substrate, and forming a carrier exclusion layer over the channel layer. The method also comprises forming a gate insulator over the carrier exclusion layer, and forming a gate on the gate insulator, wherein the carrier exclusion layer is formed of a material having a conduction band energy larger than a conduction band energy of the material from which the channel layer is formed.

The carrier exclusion layer separates the charge carriers in the channel from the interface traps at the oxide-semiconductor interface, thereby minimizing the amount of electrical charge in the channel that is drawn toward the gate.

### BRIEF DESCRIPTION OF THE DRAWINGS

The invention can be better understood with reference to the following drawings. The components in the drawings are not necessarily to scale, emphasis instead being placed upon clearly illustrating the principles of the present invention. Moreover, in the drawings, like reference numerals designate corresponding parts throughout the several views.

FIG. 1 is a schematic diagram illustrating a portion of a semiconductor device including the semiconductor layers located below the gate terminal of a field effect transistor.

FIG. 2 is a schematic diagram illustrating a metal insulator semiconductor field effect transistor (MISFET) constructed in accordance with an embodiment of the invention.

FIG. 3 is a schematic diagram illustrating an alternative transistor structure in which the carrier exclusion layer can be implemented.

FIG. 4 is a band diagram illustrating a transistor having a gallium arsenide carrier exclusion layer under a modest forward bias.

FIG. 5 is a band diagram illustrating a transistor having a gallium arsenide carrier exclusion layer near threshold voltage.

FIG. 6 is a graphical illustration comparing the intrinsic transconductance (gmi) of two exemplary indium gallium arsenide MISFET devices, each having a carrier exclusion layer, to an indium gallium arsenide HEMT device having no oxide and no carrier exclusion layer.

FIG. 7 is a flow chart illustrating a method of constructing a transistor in accordance with an embodiment of the invention.

### DETAILED DESCRIPTION OF THE INVENTION

The carrier exclusion layer will be described below as being implemented in a gallium arsenide (GaAs)-based field effect transistor (FET). However, the carrier exclusion layer can be implemented in transistors using other material systems.

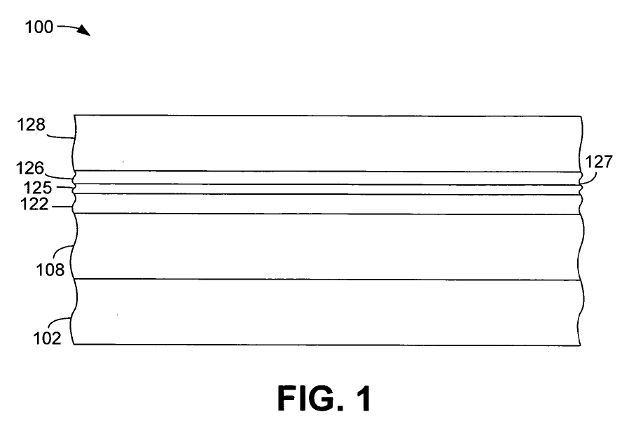

FIG. 1 is a schematic diagram illustrating a portion of a semiconductor device 100 including the semiconductor layers located below the gate terminal of a field effect transistor. The device 100 includes a gallium arsenide (GaAs) substrate 102 that can be, for example, a gallium arsenide wafer on which the material layers that form the device 100 are formed. A buffer layer 108 is formed over the substrate 102. The buffer layer 108 can be formed of, for example, gallium arsenide, aluminum gallium arsenide, layers of gallium arsenide and aluminum gallium arsenide, or other suitable materials.

The buffer layer 108 provides a suitable surface over which to grow a layer of indium gallium arsenide. A 10 nanometer (nm) thick layer of indium gallium arsenide is formed over the buffer layer 108 and forms the channel layer 122. Alternatively, the thickness of the channel layer 122 may range from approximately 5-15 nm. The channel layer 122 can be composed of Ga₁₋ₓInₓAs, where 0.35≦x≦0.15. In one embodiment, the channel layer 122 is composed of Ga_{0.75}In_{0.25}As.

A 2-3 nm thick layer of gallium arsenide is formed over the channel layer 122 and forms a carrier exclusion layer 125, also referred to as the “CEL.” The material of the carrier exclusion layer 125, in this example, is gallium arsenide while the material from which the channel layer 122 is formed is indium gallium arsenide. The gallium arsenide of the carrier exclusion layer 125 has a conduction band energy larger than the conduction band energy of the indium gallium arsenide channel layer 122 by approximately 0.25 eV, in this embodiment. For example, the conduction band energy of GaAs at the vacuum level, or zero energy state, is −4.07 electron volts (eV) and the conduction band energy for InGaAs, having 25% indium, is −4.32 eV, thus making the conduction band energy of the carrier exclusion layer 125 0.25 eV higher than the conduction band energy of the channel layer 122. In this embodiment, the indium gallium arsenide that forms the channel layer 122 is pseudomorphic so the gallium arsenide carrier exclusion layer 125 can be grown on top of it. In an alternative embodiment, the carrier exclusion layer 125 can be formed of aluminum gallium arsenide, the channel layer 122 can be formed of gallium arsenide and the buffer layer 108 can be a multiple layer structure of gallium arsenide and aluminum gallium arsenide, which are lattice matched throughout.

A 5 nm-thick layer of an insulating material is formed over the carrier exclusion layer 125 and forms an insulator 126. Alternatively, the thickness of the insulating material may range from approximately 2-10 nm. The material of the insulator 126 can be an oxide or a large bandgap semiconductor material. In one embodiment, the insulator 126 is formed of aluminum oxide (Al₂O₃). A 0.25-1.0 micrometer (μm) thick layer of metal is formed over the insulator 126 and forms the gate 128. For example, a metal, such as gold, can be used to form the gate 128.

As mentioned above, the carrier exclusion layer 125 is formed from a material that has a conduction band energy larger than the conduction band energy of the material of the channel layer 122. In a device without a carrier exclusion layer between the insulator and the semiconductor material of the channel layer, interface traps at the insulator-channel interface reduce the channel transport properties, or the channel carrier density, and thus the performance of the device, as mentioned above. By locating a carrier exclusion layer 125 between the channel layer 122 and the insulator 126 (in this example, an oxide), the insulator-channel interface is eliminated and any interface traps are relocated to the insulator-carrier exclusion layer interface 127. In this manner, the electric charge carriers in the channel 122 are physically separated from the interface traps at the insulator-carrier exclusion layer interface 127. Physically separating the electric charge carriers in the channel layer 122 from the interface traps and other imperfections at the insulator-carrier exclusion layer interface 127 significantly reduces any negative effects that these interface traps and imperfections will have on the channel transport properties. In other words, a moderate to large density of interface traps or other physical interface imperfections at the insulator-carrier exclusion layer interface 127 will not significantly impair the channel transport properties. This is because the carrier exclusion layer 125 prevents carriers in the channel layer 122 from migrating towards the interface traps at the insulator-carrier exclusion layer interface 127 when voltage on the gate 128 increases. This results in a transistor having superior device characteristics, such as high transconductance and drive current, which derive directly from the higher carrier mobility and elimination of possible carrier recombination provided by the carrier exclusion layer 125.

As the voltage applied to the gate 128 increases, electrons (i.e. electric charge carriers) in the channel layer 122 tend to be drawn toward the gate, and toward the interface traps located at the insulator-carrier exclusion layer interface 127. The carrier exclusion layer 125 helps to maximize electron density in the channel layer 122 by preventing carriers from approaching the interface traps at the insulator-carrier exclusion layer interface 127. This is because the carrier exclusion layer 125 has a thickness that separates the carriers in the channel layer 122 from the insulator-carrier exclusion layer interface 127 and because the conduction band energy of the carrier exclusion layer 125 is larger than the conduction band energy of the channel layer 122. The concentration of carriers in the channel layer 122 tends to move toward the gate 128 as the gate voltage increases. The presence of the carrier exclusion layer 125 maintains a high carrier density, and high electron mobility, in the center of the channel layer 122.

In this embodiment, the thickness of the carrier exclusion layer 125 is approximately 2 nm to 3 nm. However, depending on device parameters, a thicker or thinner carrier exclusion layer may be desirable. The thickness of the carrier exclusion layer is a tradeoff. If the carrier exclusion layer 125 is too thick, it can have two disadvantages. First, a large carrier exclusion layer thickness can reduce the transconductance of the transistor. Transconductance is a parameter that defines the relationship between the current flow in the channel of a field effect transistor, and the gate voltage (Vg). Second, as the thickness of the carrier exclusion layer increases, it allows a greater electron density at the insulator-carrier exclusion layer interface 127. However, if the carrier exclusion layer 125 is too thin, it will not provide the desired separation of interface traps and charge carriers in the channel layer 122, and will allow charge carriers to penetrate the carrier exclusion layer 125, resulting in the undesirable condition of charge being present at the insulator-carrier exclusion layer interface 127 at high gate voltages.

When implemented in the gallium arsenide material system, the carrier exclusion layer 125 can be formed of gallium arsenide, as described above, or can be formed of aluminum gallium arsenide, gallium indium phosphide, or another material having a conduction band energy larger than the conduction band energy of the material of the channel layer 122. When implemented in the gallium arsenide material system, the channel layer 122 may be formed of indium gallium arsenide, as described above, or can be formed of gallium arsenide, indium arsenide, indium phosphide, or another material having a conduction band energy lower than the conduction band energy of the material of the carrier exclusion layer 125.

The layers described herein may be grown using known growth methodologies; for example, metalorganic vapor phase epitaxy (MOVPE), also known as metalorganic chemical vapor deposition (MOCVD) and organometallic chemical vapor deposition (OMCVD), organometallic vapor phase epitaxy (OMVPE) and molecular beam epitaxy (MBE). Other growth methodologies are also possible.

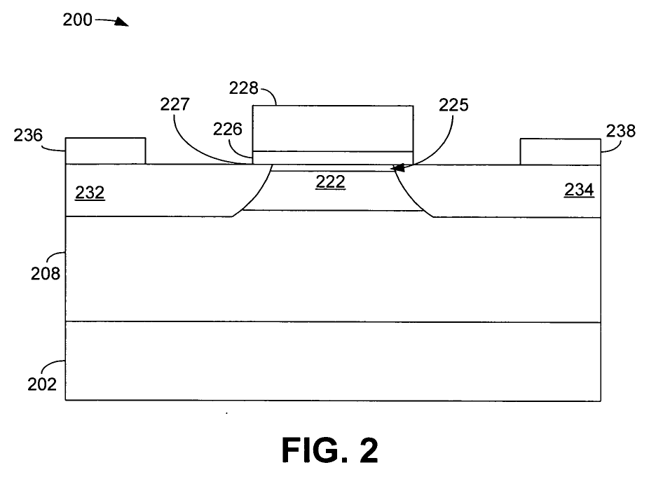

FIG. 2 is a schematic diagram illustrating a metal insulator semiconductor field effect transistor (MISFET) 200 constructed in accordance with an embodiment of the invention. The transistor 200 includes a substrate 202 of gallium arsenide over which a buffer layer 208 is formed. The buffer layer 208 can be formed of, for example, gallium arsenide, aluminum gallium arsenide, layers of gallium arsenide and aluminum gallium arsenide, or other suitable materials. A 10 nm-thick layer of indium gallium arsenide is formed over the buffer layer 208 and forms the channel layer 222. Alternatively, the thickness of the channel layer 222 may range from approximately 5-15 nm. A 2 nm-3 nm thick layer of gallium arsenide is formed over the channel layer 222 and forms the carrier exclusion layer 225. The carrier exclusion layer 225 can alternatively be formed of any semiconductor material having a conduction band energy larger than the conduction band energy of the material of the channel layer 222. In this embodiment, the indium gallium arsenide of the channel layer 222 is pseudomorphic so the gallium arsenide carrier exclusion layer 225 can be grown on top of it. In an alternative embodiment, the carrier exclusion layer 225 can be formed of aluminum gallium arsenide, the channel layer 222 can be formed of gallium arsenide and the buffer layer 208 can be formed of a multiple layer structure of gallium arsenide and aluminum gallium arsenide, which are lattice matched throughout.

The transistor 200 also includes implanted regions 232 and 234 that provide the source and drain, respectively. Located on regions 232 and 234 are the source contact 236 and the drain contact 238, respectively. A gate insulator 226 is formed over the carrier exclusion layer 225. In this embodiment, the gate insulator is an oxide; for example, aluminum oxide (Al₂O₃), but can alternatively be a large bandgap semiconductor material instead of an oxide. A gate 228 is formed over the gate insulator 226. In one embodiment, the gate 228 can be, for example, a 250 nm thick layer of titanium and a 1 μm thick layer of gold.

The transistor 200 illustrates a MISFET device in which a voltage applied to the gate allows fine control over the channel conduction characteristics, but which does not result in excessive charge being drawn away from the channel to the interface traps at the insulator-carrier exclusion layer interface 227. The carrier exclusion layer 225 provides a barrier to carriers being drawn toward the gate 228.

In an alternative implementation of the transistor 200, the drain implant 234 may be spaced away from the gate 228 to increase drain breakdown voltage and limit the maximum voltage across the gate insulator 226. Further, a lightly doped drain (LDD) or other graded doping structure can be implemented to increase drain breakdown voltage.

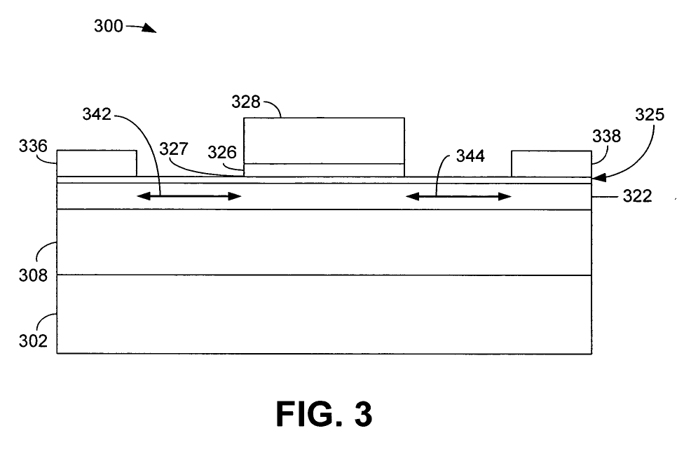

FIG. 3 is a schematic diagram illustrating an alternative transistor structure in which the carrier exclusion layer is implemented. The transistor 300 of FIG. 3 is referred to as a high electron mobility transistor (HEMT) that implements what is referred to as a “modulation doped channel.” The transistor 300 includes a gallium arsenide substrate 302 over which a buffer layer 308 is formed. The buffer layer 308 can be formed of, for example, gallium arsenide, aluminum gallium arsenide, layers of gallium arsenide and aluminum gallium arsenide, or other suitable materials. A 10 nm-thick layer of indium gallium arsenide is formed over the buffer layer 308 and forms a channel layer 322. Alternatively, the thickness of the channel layer 322 may range from approximately 5-15 nm.

A 2 nm-3 nm thick layer of gallium arsenide is formed over the channel layer 322 and forms a carrier exclusion layer 325. In this embodiment, the indium gallium arsenide that forms the channel 322 is pseudomorphic so the gallium arsenide carrier exclusion layer 325 can be grown on top of it. In an alternative embodiment, the carrier exclusion layer 325 can be formed of aluminum gallium arsenide, the channel layer 322 can be formed of gallium arsenide and the buffer layer 308 can be a multiple layer structure of gallium arsenide and aluminum gallium arsenide, which are lattice matched throughout. A 5 nm thick layer of an insulating material is formed over the carrier exclusion layer 325 and forms the gate insulator 326. Alternatively, the thickness of the insulating material may range from approximately 2-10 nm. The gate insulator can be, for example, aluminum oxide (Al₂O₃) as described above, or can be a large bandgap semiconductor material.

A 0.25-1.0 μm thick layer of metal is formed over the gate insulator 326 and forms the gate 328. In one embodiment, the gate 328 can be, for example, a 250 nm thick layer of titanium and a 1 μm thick layer of gold. A source contact 336 and drain contact 338 are formed over the carrier exclusion layer 325. The channel layer 322 comprises a modulation doped channel. Such an implementation relies on the conductivity of the access regions 342 and 344 between the channel layer 322 and the source and drain contacts 336 and 338. Access regions 342 and 344 are regions of the channel layer 322 that are not under gate control.

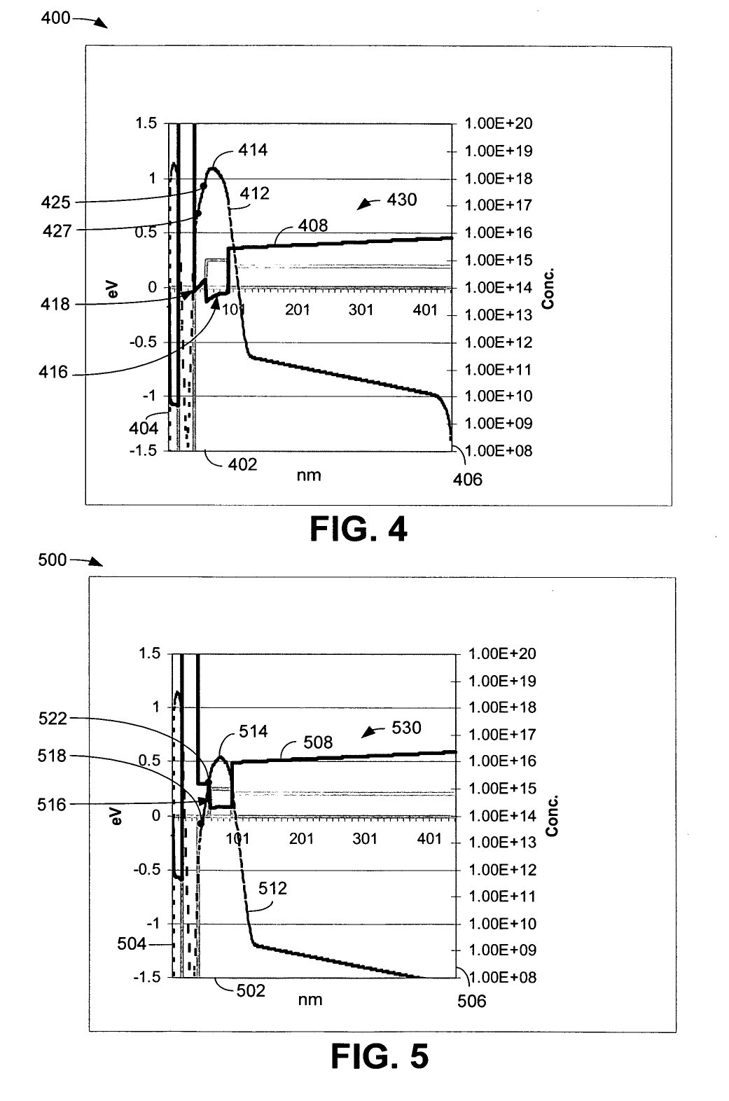

FIG. 4 is a band diagram 400 illustrating a transistor having a gallium arsenide carrier exclusion layer under a modest forward bias of 0.8V. The horizontal axis 402 represents distance or thickness of the material layers in nm, the left vertical axis 404 represents energy in electron volts (eV), and the right vertical axis 406 represents charge concentration. The curve 408 represents conduction band energy (Ecg) in electron volts (eV) and the curve 412 represents electron density (ng) in cm⁻³. As shown in FIG. 4, the electron density of curve 412 peaks at a position illustrated using reference numeral 414 at approximately 1×10¹⁹ in the indium gallium arsenide channel region indicated at 416. The carrier exclusion layer is illustrated at 418 and shows an electron density of approximately 1×10¹⁸ at the carrier exclusion layer-channel interface 425 and an electron density of approximately 1×10¹⁷ at the insulator-carrier exclusion layer-interface 427. This shows that the carrier exclusion layer greatly reduces the carrier density at the insulator-carrier exclusion layer interface 427 with respect to the carrier exclusion layer-channel interface 425. The buffer layer is indicated generally at 430 and is illustrated in FIG. 4 as a single layer of aluminum gallium arsenide. However, the buffer layer may be a multiple layer structure of gallium arsenide and aluminum gallium arsenide.

FIG. 5 is a band diagram 500 illustrating a MISFET transistor incorporating a carrier exclusion layer near threshold voltage (i.e., at a small forward bias of approximately 0.3 volts). The horizontal axis 502 represents distance or thickness of the material layers in nm, the left vertical axis 504 represents energy in the electron volts (eV) and the right vertical axis 506 represents charge concentration.

The curve 508 represents conduction band energy (Ecg) in electron volts (eV) and the curve 512 represents electron density (ng) in cm⁻³. As shown in FIG. 5, the electron density of curve 512 peaks at a position illustrated using reference numeral 514 at approximately 1×10¹⁶ in the channel region. The electron density decreases across the carrier exclusion layer from approximately 1×10¹⁵ at point 522 at the carrier exclusion layer-channel interface to approximately 1×10¹³ at point 518 at the insulator-carrier exclusion layer interface, providing a very substantial reduction at the insulator-carrier exclusion layer, which is where the interface trap density is greatest. The buffer layer is indicated generally at 530 and is illustrated in FIG. 5 as a single layer of aluminum gallium arsenide. However, the buffer layer may be a multiple layer structure of gallium arsenide and aluminum gallium arsenide.

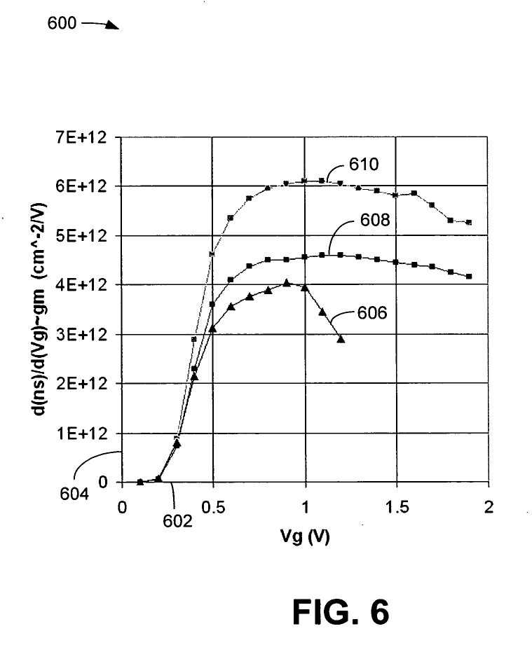

FIG. 6 is a graphical illustration 600 comparing the intrinsic transconductance (gmi) of two exemplary indium gallium arsenide MISFET devices, each having a carrier exclusion layer, to an indium gallium arsenide HEMT device having no oxide and no carrier exclusion layer. The horizontal axis 602 represents gate voltage, Vg, and the vertical axis 604 represents the transconductance for electrons in the channel of the device. The curve 606 represents a conventional HEMT device having no oxide and no carrier exclusion layer. The curve 606 shows a HEMT having a transconductance that is very high, but not very broad as a function of gate voltage. The curve 608 illustrates a MISFET device having a 7.1 nm thick oxide layer and a 2 nm thick carrier exclusion layer. The curve 610 illustrates a MISFET device having a 4 nm thick oxide layer and a 2 nm thick carrier exclusion layer.

The curves 608 and 610 illustrate that it is possible to use an oxide layer with a carrier exclusion layer to simultaneously block gate current, separate charge carriers from the interface traps, and still maintain a very high intrinsic transconductance. This is evidenced by the high transconductance shown by curves 608 and 610. In addition, this high transconductance can extend to high gate voltages because the oxide layer blocks the forward gate current.

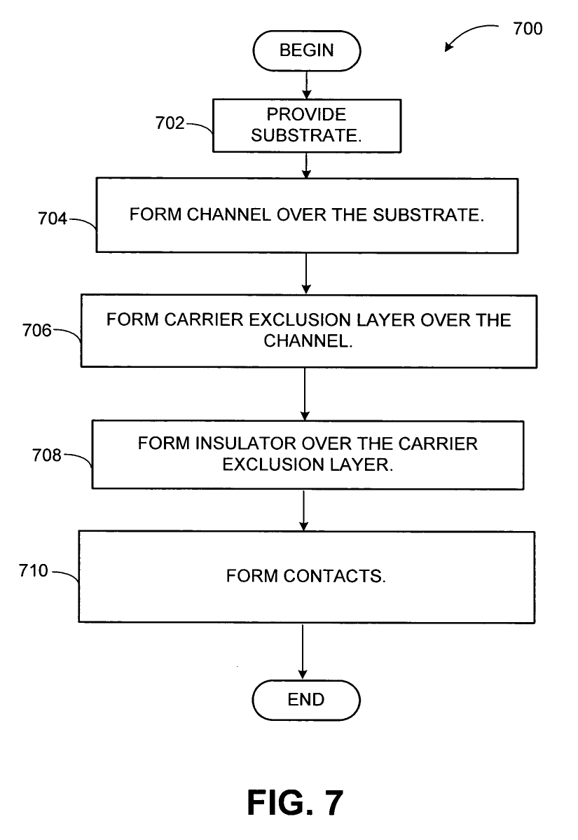

FIG. 7 is a flow chart illustrating a method of constructing a transistor in accordance with an embodiment of the invention. In block 702, a substrate is provided. In block 704, a channel layer is formed over the substrate. In block 706, a carrier exclusion layer of a material having a higher conduction band energy than the material of the channel layer is formed over the channel. In block 708, a gate insulator is formed over the carrier exclusion layer. In block 710, gate, source and drain contacts are formed.

This disclosure describes the invention in detail using illustrative embodiments. However, it is to be understood that the invention defined by the appended claims is not limited to the precise embodiments described.

1. A field-effect transistor, comprising:
a substrate;
a channel layer over the substrate;
a gate insulator;
a gate separated from the channel layer by the gate insulator; and
a carrier exclusion layer between the channel layer and the gate insulator, wherein the conduction band energy of the carrier exclusion layer is larger than the conduction band energy of the channel layer.

2. The transistor of claim 1, in which the material of the channel layer is chosen from indium gallium arsenide, gallium arsenide, indium arsenide, and indium phosphide, and the material of the carrier exclusion layer is chosen from gallium arsenide, aluminum gallium arsenide, and gallium indium phosphide.

3. The transistor of claim 2, in which the channel layer comprises indium gallium arsenide and the carrier exclusion layer comprises gallium arsenide.

4. The transistor of claim 3, in which the channel layer comprises Ga₁₋ₓInₓAs, where 0.35≦x≦0.15, and the carrier exclusion layer comprises GaAs.

5. The transistor of claim 4, in which the channel layer comprises Ga_{0.75}In_{0.25}As and the carrier exclusion layer comprises GaAs.

6. The transistor of claim 3, in which the channel layer is pseudomorphically grown.

7. The transistor of claim 2, in which the transistor is a metal insulator field effect transistor (MISFET).

8. The transistor of claim 2, in which the transistor is a high electron mobility transistor (HEMT).

9. A method of making a field-effect transistor, the method comprising:
providing a substrate;
forming a channel layer over the substrate;
forming a carrier exclusion layer over the channel layer;
forming a gate insulator over the carrier exclusion layer; and
forming a gate on the gate insulator, wherein the carrier exclusion layer is formed of a material having a conduction band energy larger than a conduction band energy of the material from which the channel layer is formed.

10. The method of claim 9, wherein:
forming the channel layer comprises forming the channel layer of a material chosen from indium gallium arsenide, gallium arsenide, indium arsenide, and indium phosphide; and
forming the carrier exclusion layer comprises forming the carrier exclusion layer of a material chosen from gallium arsenide, aluminum gallium arsenide, and gallium indium phosphide.

11. The method of claim 10, wherein forming the channel layer comprises forming the channel layer of indium gallium arsenide and forming the carrier exclusion layer comprises forming the carrier exclusion layer of gallium arsenide.

12. The method of claim 11, in which forming the channel layer comprises forming the channel layer of Ga₁₋ₓInₓAs, where 0.35≦x≦0.15, and forming the carrier exclusion layer comprises forming the carrier exclusion layer of GaAs.

13. The method of claim 12, in which forming the channel layer comprises forming the channel layer of Ga_{0.75}In_{0.25}As and forming the carrier exclusion layer comprises forming the carrier exclusion layer of GaAs.

14. The method of claim 11, in which forming the channel layer comprises forming the channel layer pseudomorphically.

15. The method of claim 10, in which the transistor is a metal insulator field effect transistor (MISFET).

16. The method of claim 10, in which the transistor is a high electron mobility transistor (HEMT).

17. A field-effect transistor, comprising:
a substrate of gallium arsenide;
a channel layer comprising indium gallium arsenide over the substrate;
a gate insulator comprising aluminum oxide (Al₂O₃);
a gate separated from the channel layer by the gate insulator; and
a carrier exclusion layer of gallium arsenide between the channel layer and the insulator.

18. The transistor of claim 17, in which the channel layer comprises Ga₁₋ₓInₓAs, where 0.35≦x≦0.15, and the carrier exclusion layer comprises GaAs.

19. The transistor of claim 18, in which the channel layer comprises Ga_{0.75}In_{0.25}As and the carrier exclusion layer comprises GaAs.
